(19) United States
(12) Patent Application Publication
(10) Pub. No.: US 2026/0056080 A1
(43) Pub. Date: Feb. 26, 2026

(54) Charging Dock

(71) Applicants: Tyco Electronics (Suzhou) Ltd., Suzhou City (CN); Tyco Electronics (Shanghai) Co., Ltd., Shanghai (CN); Tyco Electronics Technology (SIP) Co., Ltd., Suzhou (CN)

(72) Inventors: Guangrui (Gary) Wu, Suzhou (CN); Fangyue (Jason) Zhu, Shanghai (CN); Jinshun (Jet) Wang, Suzhou (CN); Houtie (Jack) Liu, Suzhou (CN)

(73) Assignees: Tyco Electronics (Suzhou) Ltd., Suzhou City (CN); Tyco Electronics (Shanghai) Co., Ltd., Shanghai (CN); Tyco Electronics Technology (SIP) Co., Ltd., Suzhou (CN)

(21) Appl. No.: 19/306,036

(22) Filed: Aug. 21, 2025

(30) Foreign Application Priority Data
Aug. 21, 2024 (CN) 202411150055.0

(51) Int. Cl. G01M 3/18; B60L 53/16; H01R 13/00; H01R 13/52; H01R 13/66; H01R 24/22; H01R 103/00; H05K 7/20

(52) U.S. Cl. CPC G01M 3/183; H01R 13/005; H01R 13/5208; H01R 13/6683; H01R 24/22; H05K 7/20272; B60L 53/16; H01R 2103/00; H01R 2201/26

(57) ABSTRACT

A charging dock includes a housing, a ground terminal disposed in the housing, a power supply terminal disposed in the housing and electrically connected to a power cord, a liquid cooling module mounted in the housing for cooling the charging dock, a grounding member disposed in the housing and electrically connected to the ground terminal, and a leakage detection member disposed in the housing and electrically connected to the grounding member and the ground terminal. The leakage detection member is in contact with the liquid cooling module such that the leakage detection member is electrically connected to the power supply terminal via a coolant leaking from the liquid cooling module. Whether there is liquid leakage in the liquid cooling module is detected by detecting a current on the grounding member.

### CROSS-REFERENCE TO RELATED APPLICATION

This application claims the benefit of the filing date under 35 U.S.C. § 119(a)-(d) of Chinese Patent Application No. 202411150055.0, filed on Aug. 21, 2024.

### FIELD OF THE INVENTION

The present invention relates to a charging dock.

### BACKGROUND OF THE INVENTION

A charging dock typically includes a charging dock housing, a charging terminal (or a power supply terminal) disposed in the charging dock housing, and a charging cable (or a power cord) electrically connected to the charging terminal. In order to increase the charging speed, a charging current needs to be increased, and the current charging current is required to be up to 600 A, and may also rise to 1000 A. When this large current flows through the charging cable and the charging terminal, it causes the temperature inside the charging dock housing and the temperature of the charging cable to rise sharply.

In order to prevent an excessive temperature rise, there are two common solutions. One solution is to increase the diameter of the charging cable, but this increases the volume and weight of a charging dock product and leads to higher costs. The other solution is to install a liquid cooling module in the charging dock housing, and the liquid cooling module is utilized to cool the charging cable and the charging terminal. For the solution of liquid cooling, there is a problem of leakage, and the existing charging dock product is not provided with a device capable of timely detecting leakage, which leads to safety accidents such as electric shock.

### SUMMARY OF THE INVENTION

A charging dock includes a housing, a ground terminal disposed in the housing, a power supply terminal disposed in the housing and electrically connected to a power cord, a liquid cooling module mounted in the housing for cooling the charging dock, a grounding member disposed in the housing and electrically connected to the ground terminal, and a leakage detection member disposed in the housing and electrically connected to the grounding member and the ground terminal. The leakage detection member is in contact with the liquid cooling module such that the leakage detection member is electrically connected to the power supply terminal via a coolant leaking from the liquid cooling module. Whether there is liquid leakage in the liquid cooling module is detected by detecting a current on the grounding member.

### BRIEF DESCRIPTION OF THE DRAWINGS

Features of the present invention will become more apparent by describing in detail exemplary embodiments thereof with reference to the accompanying drawings, in which:

FIG. 1 shows an illustrative perspective view of a charging dock according to an exemplary embodiment of the present disclosure, as viewed from the top;

FIG. 2 shows an illustrative perspective view of a charging dock according to an exemplary embodiment of the present disclosure, as viewed from the bottom;

FIG. 3 shows an illustrative perspective view of a charging dock according to an exemplary embodiment of the present disclosure as viewed from the bottom, with an intermediate housing removed;

FIG. 4 shows an illustrative perspective view of a charging dock according to an exemplary embodiment of the present disclosure as viewed from the top, with an upper housing removed;

FIG. 5 shows an illustrative perspective view of an intermediate housing, a grounding member and a leakage detection member of a charging dock according to an exemplary embodiment of the present disclosure;

FIG. 6 shows an illustrative perspective view of a charging dock according to an exemplary embodiment of the present disclosure as viewed from the top, with an upper housing and an intermediate housing removed;

FIG. 7 shows an illustrative perspective view of a charging dock according to an exemplary embodiment of the present disclosure as viewed from the top, with a rear end cover and a seal removed;

FIG. 8 shows an illustrative perspective view of an electrical connection module and a liquid cooling module of a charging dock according to an exemplary embodiment of the present disclosure;

FIG. 9 shows an illustrative perspective view of a liquid cooling module of a charging dock according to an exemplary embodiment of the present disclosure;

FIG. 10 shows an illustrative perspective view of an electrical connection module of a charging dock according to an exemplary embodiment of the present disclosure;

FIG. 11 shows an illustrative perspective view of a power supply terminal, a ground terminal, a grounding member and a leakage detection member of a charging dock according to an exemplary embodiment of the present disclosure;

FIG. 12 shows an illustrative perspective view of an electrical connection module of a charging dock according to an exemplary embodiment of the present disclosure;

FIG. 13 shows an illustrative perspective view of a leakage detection device of a charging dock according to an exemplary embodiment of the present disclosure; and

FIG. 14 shows an illustrative exploded view of a leakage detection device of a charging dock according to an exemplary embodiment of the present disclosure.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

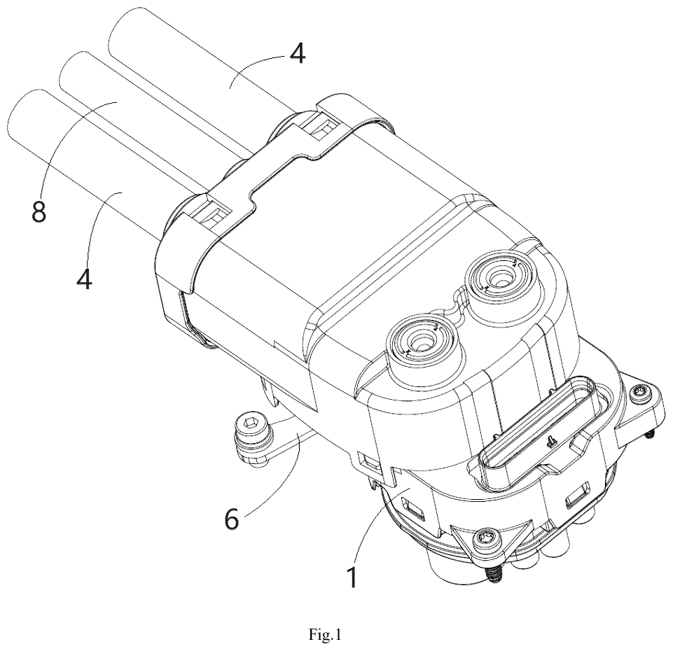

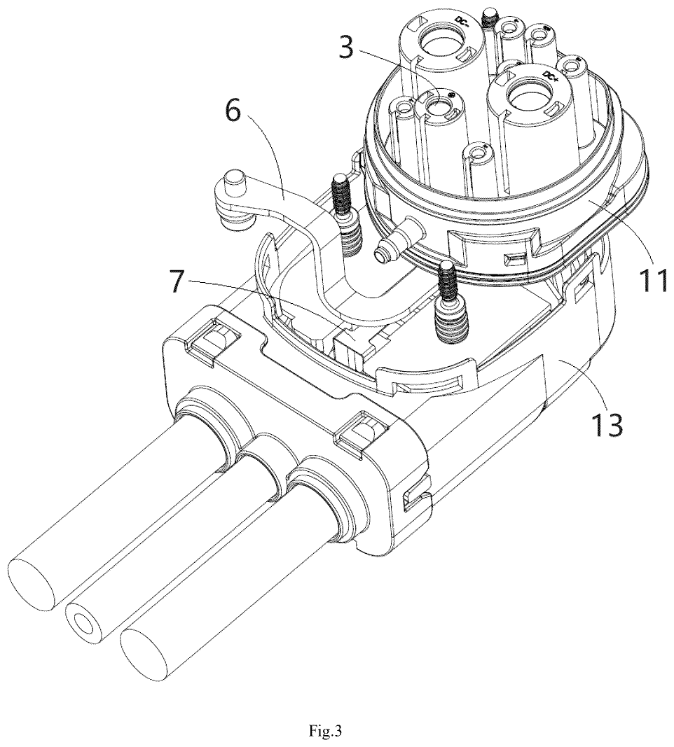

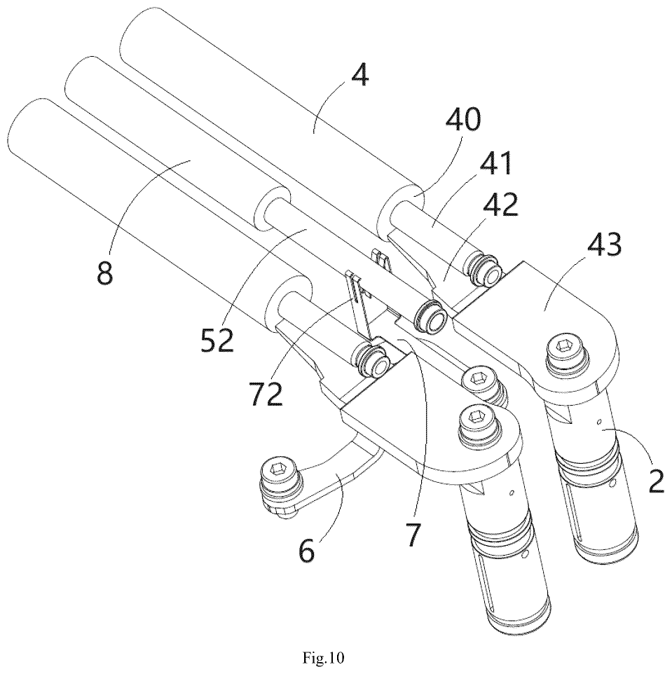

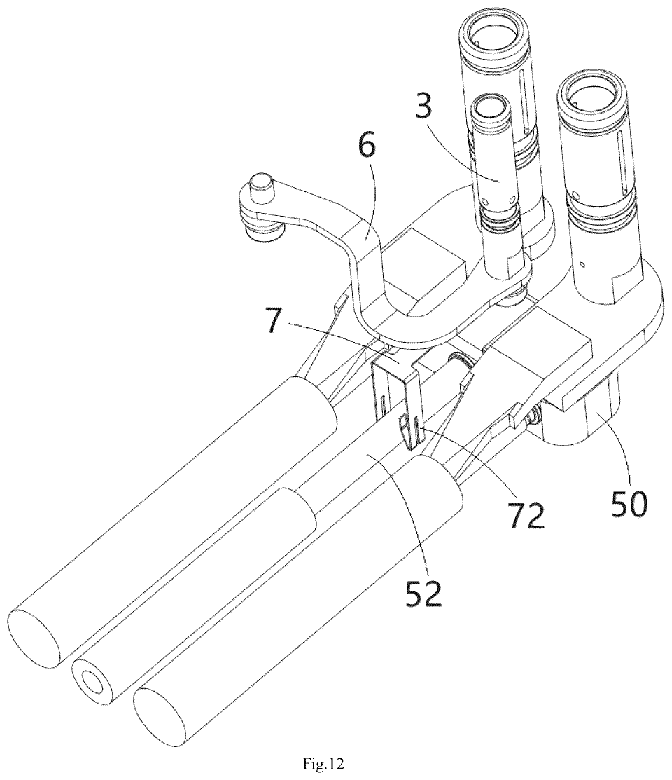

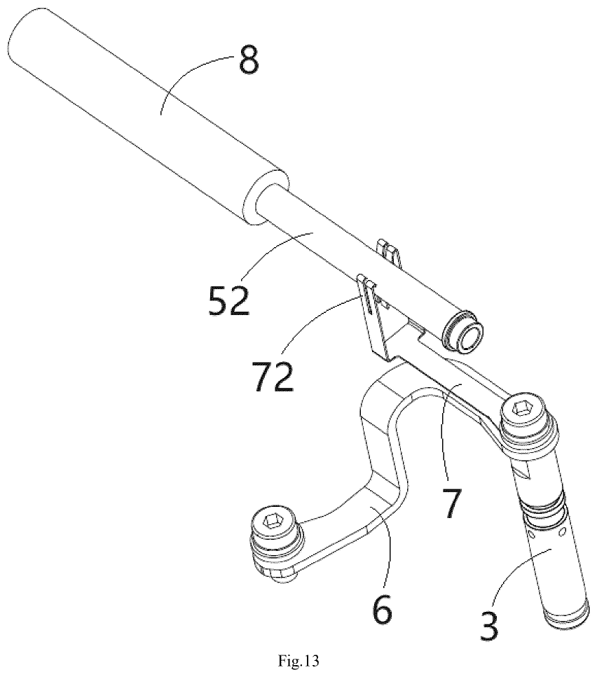

As shown in FIGS. 1 to 14, in an exemplary embodiment of the present invention, a charging dock is disclosed. The charging dock includes: a housing 1, a power supply terminal 2, a ground terminal 3, a liquid cooling module 5, a grounding member 6, and a leakage detection member 7. The ground terminal 3 is disposed in the housing 1. The power supply terminal 2 is disposed in the housing 1 for electrical connection to a power cord 4. The liquid cooling module 5 is mounted in the housing 1 for cooling the charging dock. The grounding member 6 is disposed in the housing 1 and is electrically connected to the ground terminal 3. The leakage detection member 7 is disposed in the housing 1 and is electrically connected to the grounding member 6 and the ground terminal 3. The leakage detection member 7 is in contact with the liquid cooling module 5, such that the leakage detection member 7 is capable of being electrically connected to the power supply terminal 2 via a coolant leaking from the liquid cooling module 5, and thereby enabling detection of whether there is liquid leakage in the liquid cooling module 5 by detecting a current on the grounding member 6.

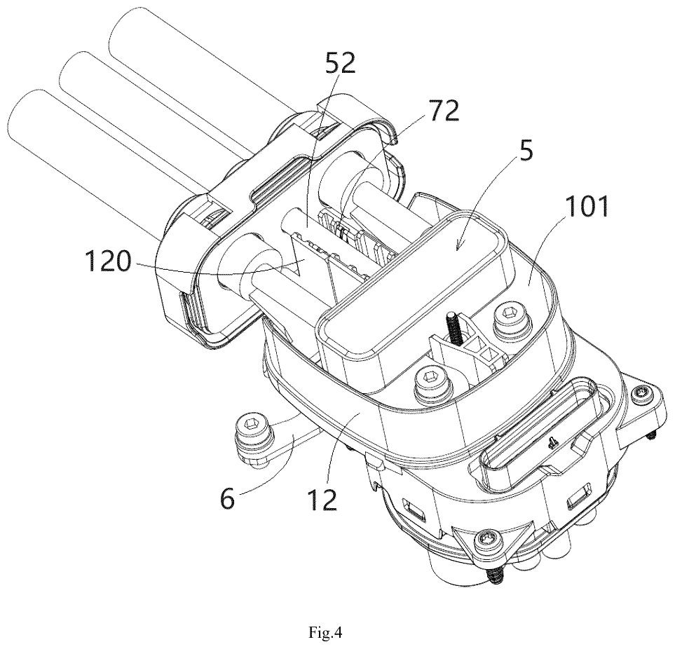

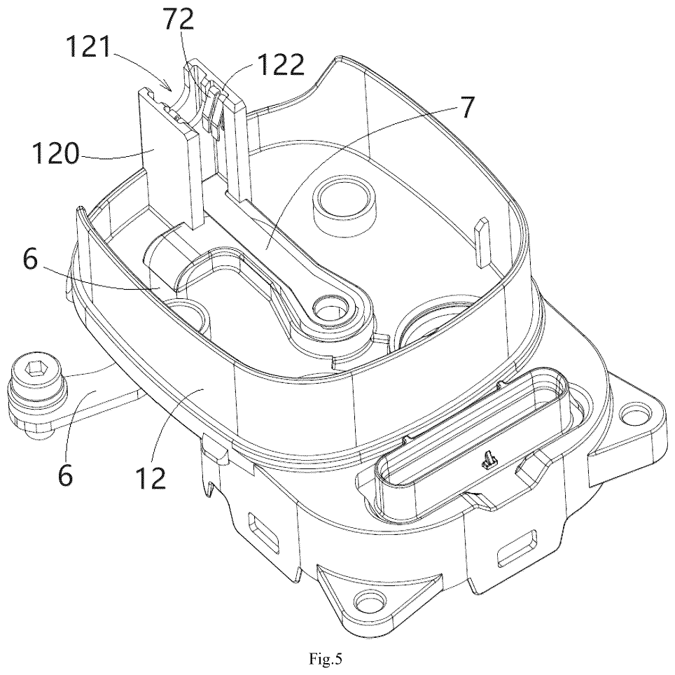

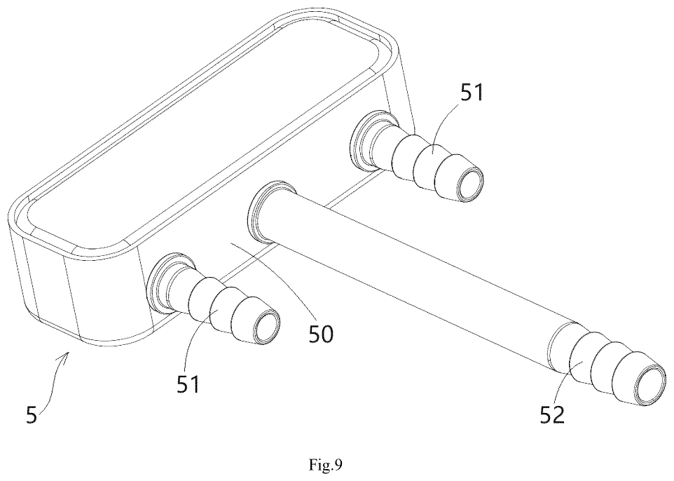

As shown in FIG. 9, in the illustrated embodiment, the liquid cooling module 5 includes: a liquid cooling tank 50, a liquid inlet pipe joint 51, and a liquid outlet pipe joint 52. The liquid cooling tank 50 is for containing the coolant. The liquid inlet pipe joint 51 is connected to the liquid cooling tank 50. The liquid outlet pipe joint 52 is connected to the liquid cooling tank. The coolant flows into the liquid cooling tank 50 via the liquid inlet pipe joint 51 and flows out of the liquid cooling tank 50 via the liquid outlet pipe joint 52. The leakage detection member 7, as shown in FIGS. 4 and 5, is in contact with the liquid inlet pipe joint 51 and/or the liquid outlet pipe joint 52 of the liquid cooling module 5.

As shown in FIGS. 4-6 and 8, in the illustrated embodiment, the leakage detection member 7 has an elastic arm 72. The elastic arm 72 is in contact with the liquid inlet pipe joint 51 and/or the liquid outlet pipe joint 52. In the illustrated embodiment, the leakage detection member 7 has a pair of elastic arms 72. The liquid inlet pipe joint 51 or the liquid outlet pipe joint 52 is clamped between the pair of elastic arms 72.

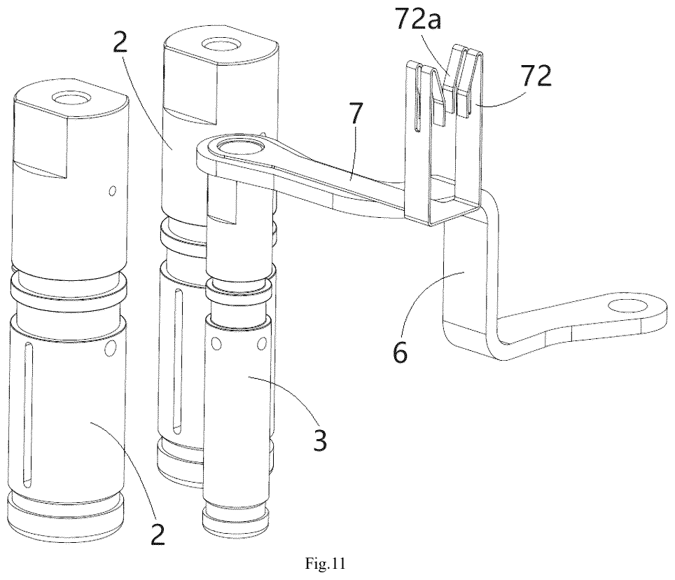

In the illustrated embodiment, the leakage detection member 7 has a plurality of pairs of elastic arms 72. Either of the liquid inlet pipe joint 51 and the liquid outlet pipe joint 52 is clamped between at least one pair of elastic arms 72. The elastic arm 72 has a plurality of spring contacts 72a arranged side by side, as shown in FIG. 11. The plurality of spring contacts 72a each is in contact with the liquid inlet pipe joint 51 or the liquid outlet pipe joint 52, which improves contact reliability.

As shown in FIG. 5, in the illustrated embodiment, the housing 1 has a retaining portion 120. A positioning groove 121 for positioning the liquid inlet pipe joint 51 or the liquid outlet pipe joint 52 is formed in the retaining portion 120. A retaining groove 122 is formed in an inner wall surface of the positioning groove 121, and the elastic arm 72 of the leakage detection member 7 is retained in the retaining groove 122, to prevent excessive deformation of the elastic arm 72.

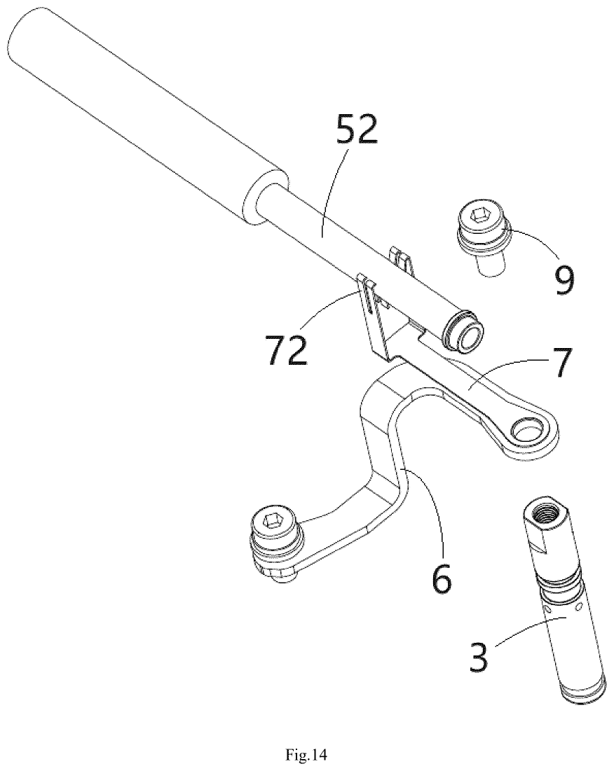

One end of the grounding member 6 and the leakage detection member 7 is fastened to the ground terminal 3 by a threaded connection member 9, shown in FIG. 14. The other end of the grounding member 6 extends from the housing 1, and the other end of the grounding member 6 is used to mate with a mating ground terminal in a charging gun.

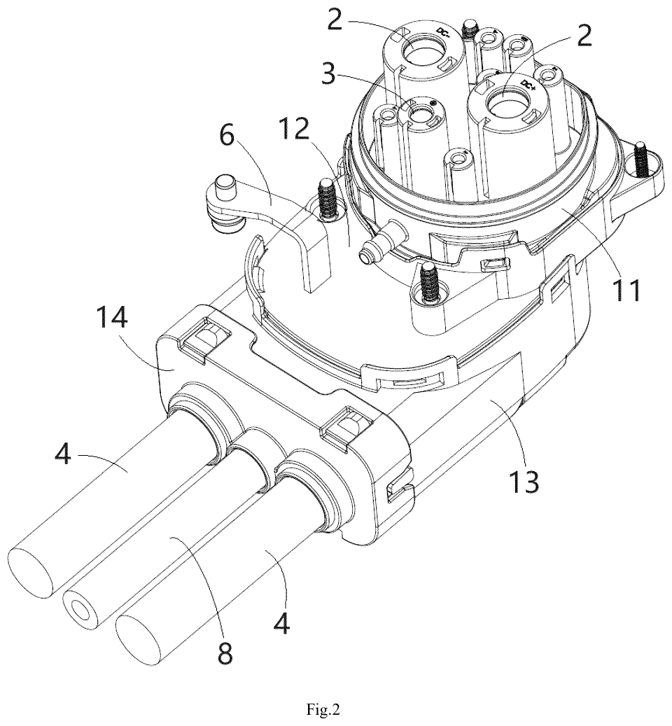

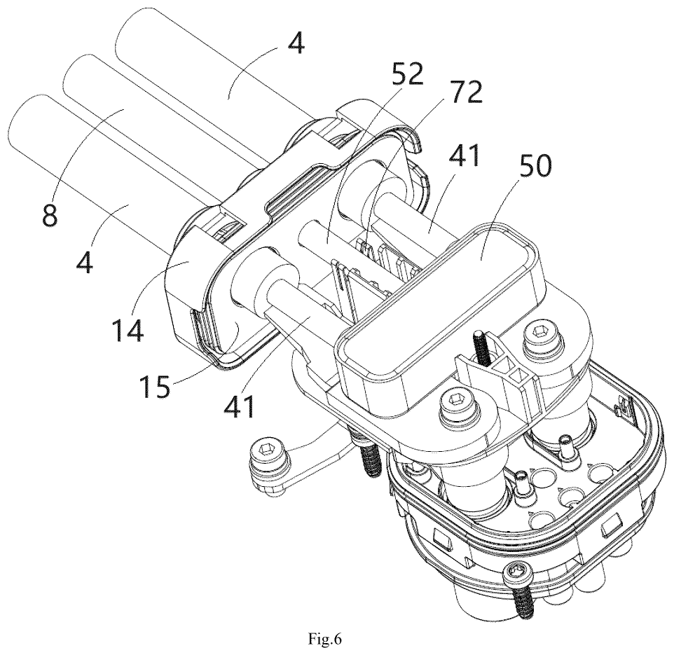

The charging dock further includes a power cord 4, as shown in FIGS. 1 and 2. The power cord 4 includes a cooling core tube 41, a conductive core 42, and an external insulation 40 wrapping the cooling core tube 41 and the conductive core 42, as shown in FIGS. 6, 8, and 10. One end of the conductive core 42 extends into the housing 1 and is electrically connected to the power supply terminal 2. One end of the cooling core tube 41 extends into the housing 1 and is connected to the liquid outlet pipe joint 52 of the liquid cooling module 5, so that a cooling fluid is capable of flowing through the cooling core tube 41 of the power cord 4 to cool the power cord 4.

As shown in FIGS. 1, 2, 6, 8, and 10, in the illustrated embodiment, the charging dock further includes a liquid inlet pipe 8. The liquid inlet pipe 8 is connected to the liquid inlet pipe joint 51 for connecting the liquid cooling module 5 to a liquid cooling circuit. One end of the liquid inlet pipe joint 51 extends from the housing 1 and is connected to the liquid inlet pipe 8.

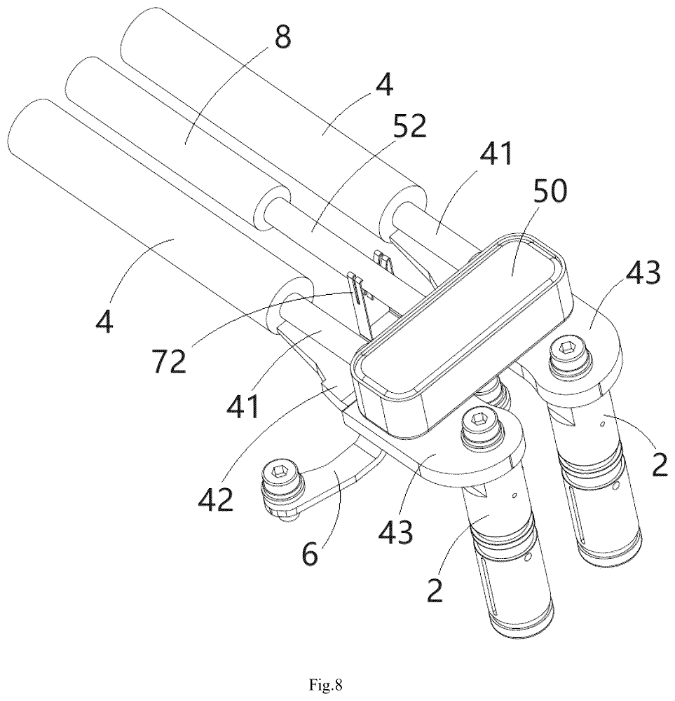

As shown in FIG. 8, in the illustrated embodiment, the conductive core 42 of the power cord 4 has an exposed flat-shaped connection end. The charging dock further includes a connection terminal 43. The connection terminal 43 is electrically connected between the connection end of the conductive core 42 and the power supply terminal 2.

In the illustrated embodiment, the connection terminal 43 is flat-shaped. The connection end of the conductive core 42 is soldered to one side of one end of the connection terminal 43, and the liquid cooling tank 50 of the liquid cooling module 5 is in thermal contact with the other side of the connection terminal 43. In the illustrated embodiment, the other end of the connection terminal 43 is fastened to one end of the power supply terminal 2 via a threaded connection member, and the other end of the power supply terminal 2 is used to mate with a mating power supply terminal 2 in a charging gun.

In the illustrated embodiment, the charging dock includes two power supply terminals 2 and two power cords 4. The liquid cooling module 5 includes two liquid outlet pipe joints 52. The conductive cores 42 of the two power cords 4 are respectively electrically connected to the two power supply terminals 2, and the cooling core tubes 41 of the two power cords 4 are respectively connected to the two liquid outlet pipe joints 52 of the liquid cooling module 5.

As shown in FIGS. 2-4 and 7, in the illustrated embodiment, the housing 1 includes a lower housing 11, an intermediate housing 12, and an upper housing 13. The lower housing 11 has a mating end 110 adapted to mate with a charging gun. The intermediate housing 12 is mounted to an upper end of the lower housing 11. The upper housing 13 is mounted to an upper end of the intermediate housing. An accommodating cavity 101 is defined between the upper housing 13 and the intermediate housing 12. The liquid cooling module 5, the grounding member 6 and the leakage detection member 7 are accommodated in the accommodating cavity. One end of each of the power supply terminal 2 and the ground terminal 3 is located in the accommodating cavity 101 and the other end of each of the power supply terminal 2 and the ground terminal 3 is located in the lower housing 11 to mate with a mating power supply terminal 2 and a mating ground terminal 3 of the charging gun, respectively.

In the illustrated embodiment, the intermediate housing 12 is injection-molded onto the grounding member 6, so that the intermediate housing 12 and the grounding member 6 become an integral part.

As shown in FIGS. 4 and 5, in the illustrated embodiment, the intermediate housing 12 has a retaining portion 120 located in the accommodating cavity 101. A positioning groove 121 for positioning the liquid inlet pipe joint 51 or the liquid outlet pipe joint 52 is formed in the retaining portion 120, and a retaining groove 122 is formed in an inner wall surface of the positioning groove 121. The leakage detection member 7 has an elastic arm 72 in contact with the liquid inlet pipe joint 51 or the liquid outlet pipe joint 52 of the liquid cooling module 5. The elastic arm 72 is retained in the retaining groove 122 of the retaining portion 120 and is in contact with the liquid inlet pipe joint 51 or the liquid outlet pipe joint 52. In the illustrated embodiment, the liquid inlet pipe joint 51 is positioned in the positioning groove 121, and the elastic arm 72 is in contact with the liquid inlet pipe joint 51.

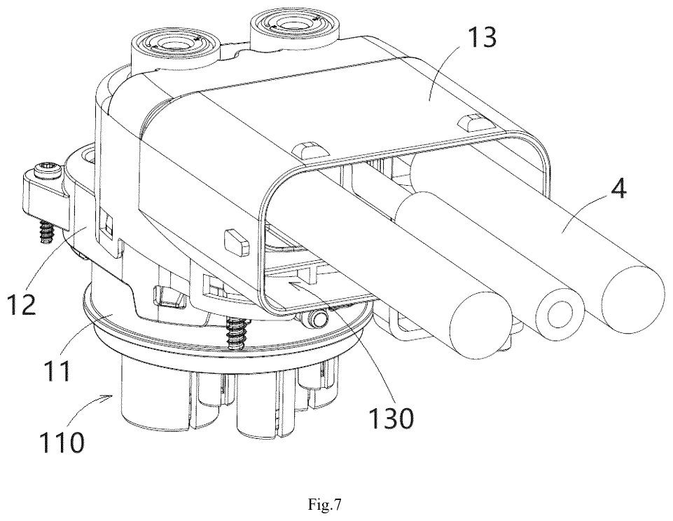

As shown in FIG. 7, in the illustrated embodiment, the upper housing 13 has a rear port 130, and the power cord 4 extends into the rear port 130 of the upper housing 13 in a direction perpendicular to an axial direction of the power supply terminal 2.

As shown in FIG. 6, in the illustrated embodiment, the charging dock further includes a rear end cover 14 and a seal 15. The rear end cover 14 is mounted onto the rear port 130 of the upper housing 13. The seal 15 is mounted into the rear port 130 of the upper housing 13. The power cord 4 and the liquid inlet pipe joint 51 pass through the rear end cover 14 and the seal 15. The rear end cover 14 fixes the power cord 4 to the rear end of the upper housing 13, and the seal 15 seals the rear port 130 of the upper housing 13.

In the aforementioned exemplary embodiments according to the present disclosure, a charging dock has a leakage detection device capable of detecting whether a liquid cooling module leaks in time, which improves the safety of use of the charging dock.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A charging dock, comprising:
a housing;
a ground terminal disposed in the housing;
a power supply terminal disposed in the housing and electrically connected to a power cord;
a liquid cooling module mounted in the housing for cooling the charging dock;
a grounding member disposed in the housing and electrically connected to the ground terminal; and
a leakage detection member disposed in the housing and electrically connected to the grounding member and the ground terminal, the leakage detection member is in contact with the liquid cooling module such that the leakage detection member is electrically connected to the power supply terminal via a coolant leaking from the liquid cooling module, whether there is liquid leakage in the liquid cooling module is detected by detecting a current on the grounding member.

2. The charging dock according to claim 1, wherein the liquid cooling module includes:
a liquid cooling tank containing the coolant;
a liquid inlet pipe joint connected to the liquid cooling tank; and
a liquid outlet pipe joint connected to the liquid cooling tank, the coolant flows into the liquid cooling tank via the liquid inlet pipe joint and flows out of the liquid cooling tank via the liquid outlet pipe joint, the leakage detection member is in contact with the liquid inlet pipe joint and/or the liquid outlet pipe joint of the liquid cooling module.

3. The charging dock according to claim 2, wherein the leakage detection member has an elastic arm in contact with the liquid inlet pipe joint and/or the liquid outlet pipe joint.

4. The charging dock according to claim 3, wherein the elastic arm is one of a pair of elastic arms, the liquid inlet pipe joint or the liquid outlet pipe joint being clamped between the pair of elastic arms.

5. The charging dock according to claim 3, wherein the leakage detection member has a plurality of pairs of elastic arms, either of the liquid inlet pipe joint and the liquid outlet pipe joint being clamped between at least one pair of elastic arms.

6. The charging dock according to claim 3, wherein the elastic arm has a plurality of spring contacts arranged side by side, the plurality of spring contacts each being in contact with the liquid inlet pipe joint or the liquid outlet pipe joint.

7. The charging dock according to claim 3, wherein the housing has a retaining portion, a positioning groove for positioning the liquid inlet pipe joint or the liquid outlet pipe joint is formed in the retaining portion, a retaining groove is formed in an inner wall surface of the positioning groove, the elastic arm of the leakage detection member is retained in the retaining groove.

8. The charging dock according to claim 1, wherein an end of the grounding member and the leakage detection member are fastened to the ground terminal by a threaded connection member, an other end of the grounding member extends from the housing, the other end of the grounding member is matable with a mating ground terminal in a charging gun.

9. The charging dock according to claim 2, further comprising the power cord including a cooling core tube, a conductive core, and an external insulation wrapping the cooling core tube and the conductive core, an end of the conductive core extends into the housing and is electrically connected to the power supply terminal, and an end of the cooling core tube extends into the housing and is connected to the liquid outlet pipe joint of the liquid cooling module, the coolant flows through the cooling core tube of the power cord to cool the power cord.

10. The charging dock according to claim 9, further comprising a liquid inlet pipe connected to the liquid inlet pipe joint for connecting the liquid cooling module to a liquid cooling circuit, an end of the liquid inlet pipe joint extends from the housing and is connected to the liquid inlet pipe.

11. The charging dock according to claim 9, wherein the conductive core of the power cord has a connection end that is exposed and has a flat shape, the charging dock includes a connection terminal electrically connected between the connection end of the conductive core and the power supply terminal.

12. The charging dock according to claim 11, wherein the connection terminal is flat-shaped, the connection end of the conductive core is soldered to a side of an end of the connection terminal, the liquid cooling tank of the liquid cooling module is in thermal contact with another side of the connection terminal.

13. The charging dock according to claim 12, wherein another end of the connection terminal is fastened to an end of the power supply terminal via a threaded connection member, another end of the power supply terminal is matable with a mating power supply terminal in a charging gun.

14. The charging dock according to claim 9, the power supply terminal is one of a pair of power supply terminals and the power cord is one of a pair of power cords, the liquid outlet pipe joint is one of a pair of liquid outlet pipe joints, the conductive cores of the power cords are electrically connected to the power supply terminals, the cooling core tubes of the power cords are connected to the liquid outlet piper joints of the liquid cooling module.

15. The charging dock according to claim 1, wherein the housing includes:
a lower housing having a mating end matable with a charging gun;
an intermediate housing mounted to an upper end of the lower housing; and
an upper housing mounted to an upper end of the intermediate housing, an accommodating cavity is defined between the upper housing and the intermediate housing, the liquid cooling module, the grounding member, and the leakage detection member are accommodated in the accommodating cavity.

16. The charging dock according to claim 15, wherein an end of each of the power supply terminal and the ground terminal is located in the accommodating cavity, and another end of each of the power supply terminal and the ground terminal is located in the lower housing to mate with a mating power supply terminal and a mating ground terminal of the charging gun.

17. The charging dock according to claim 16, wherein the intermediate housing is injection-molded onto the grounding member, the intermediate housing and the grounding member are an integral part.

18. The charging dock according to claim 15, wherein the intermediate housing has a retaining portion located in the accommodating cavity, a positioning groove for positioning a liquid inlet pipe joint or a liquid outlet pipe joint is formed in the retaining portion, and a retaining groove is formed in an inner wall surface of the positioning groove, the leakage detection member has an elastic arm in contact with the liquid inlet pipe joint or the liquid outlet pipe joint, the elastic arm is retained in the retaining groove of the retaining portion and is in contact with the liquid inlet pipe joint or the liquid outlet pipe joint.

19. The charging dock according to claim 15, wherein the upper housing has a rear port, and the power cord extends into the rear port of the upper housing in a direction perpendicular to an axial direction of the power supply terminal.

20. The charging dock according to claim 19, further comprising a rear end cover mounted onto the rear port of the upper housing and a seal mounted into the rear port of the upper housing, the power cord and a liquid inlet pipe joint pass through the rear end cover and the seal, the rear end cover fixes the power cord to a rear end of the upper housing, the seal seals the rear port of the upper housing.
